(19) United States
(12) Patent Application Publication
(10) Pub. No.: US 2023/0013801 A1
(43) Pub. Date: Jan. 19, 2023

(54) THERMOSTAT ESCUTCHEON

(71) Applicant: JEFFERY BARON LESPERANCE, HOWELL, MI (US)

(72) Inventor: JEFFERY BARON LESPERANCE, HOWELL, MI (US)

(21) Appl. No.: 17/866,526

(22) Filed: Jul. 17, 2022

Related U.S. Application Data
(60) Provisional application No. 63/222,644, filed on Jul. 16, 2021.

(51) Int. Cl. F24F 11/523; F24F 11/89

(52) U.S. Cl. CPC F24F 11/523; F24F 11/89; F24F 2221/26

(57) ABSTRACT

The disclosure provides a thermostat escutcheon for use in surrounding a thermostat mounted to a surface, such as a wall. The escutcheon allows for thermostat replacement without any additional work to the mounting wall as a result of incomplete coverage of the replacement thermostat over the prior thermostat position on the wall. The escutcheon may include surface decorations to enhance the decor of the thermostat and surrounding environment. The escutcheon may be formed in one or more elements to allow for installation after thermostat replacement. The escutcheon may be formed in a variety of shapes, such as geometric shapes or shapes resembling other objects for additional decoration and customization.

### CROSS-REFERENCE TO RELATED APPLICATIONS

This application claims priority benefit of U.S. Provisional Application(s) No. 63/222,644 filed on Jul. 16, 2021, the entire contents and disclosures of which is/are incorporated herein by reference.

### BACKGROUND

### 1. Field of the Disclosure

This disclosure is directed to a thermostat escutcheon. The disclosure is also directed to a thermostat escutcheon for use with changing from one thermostat to another thermostat, such as an intelligent or Internet-enabled thermostat.

### 2. Description of the Background

Most living spaces and habitable areas within buildings include some form of climate control. Climate control is often done at least in part, through the use of a thermostat. Recently, thermostats have evolved from a simple, manual thermostat to programmable, and increasingly, Internet-enabled “smart” thermostats. In most cases, these thermostats are mounted on a wall within the buildings or structures.

For existing structures with traditional or basic thermostats, there is often an incentive to upgrade to a programmable or “smart” thermostat. For example, an energy supply company may provide a rebate or coupon to encourage its customers to upgrade to a smart thermostat. In other cases, the user (home owner, building operator, etc.) may want to upgrade to a smart thermostat in order to operate the building or space more efficiently (i.e., save money). Whatever the situation, the basic premise is the same—replacing an existing “dumb” thermostat with a smart thermostat or upgrading/switching to another smart thermostat. In many cases, the old thermostat is replaced at a separate time from when the wall is due to be repainted/re-wallpapered.

The problem arises with the conditions of the walls themselves. Often walls are decorated with paint, wallpaper, or other surface improvements. The existing thermostat is typically secured to the wall with a plurality of screws. What is often the case is that removing the old thermostat reveals earlier wall decorations/paint/wallpaper and the holes in the wall which likely need to be patched or otherwise repaired. This is due to the fact that when a building is constructed, the walls are typically painted and/or wallpapered before the thermostat is installed (i.e., rough wiring is exposed for the later installation of the thermostat).

Another situation is that the original thermostat is installed before the walls are painted/wallpapered and so the wall behind the thermostat is left unpainted or un-wallpapered. Thus, removing the old thermostat reveals either a bare wall, a wall painted a previous color, or a wallpapered wall that does not match the current appearance of the rest of the wall. Typically, the new thermostat does not have the same shape or profile as the old thermostat, so a portion of the wall that is exposed by the profile of the new thermostat, appears unpleasant, and ruins the overall experience of upgrading the thermostat. This situation makes the upgrade less appealing due to the additional work required.

Indeed, it is possible that the upgrade may not occur due to the exposed portion of the wall as a result of the new thermostat not matching the old thermostat footprint or the upgrade may be delayed until the wall is repainted or re-wallpapered.

It may be extremely difficult to resolve this situation. Often painted walls age over time, due to exposure to the air, sunlight, and other contaminants. Retouching the wall portion left exposed due to the different profile (footprint) of the new thermostat may be very obvious and leave an overall unprofessional look. Other times, additional old paint may not be available at all, leaving the installer to try to match paint, often with poor results. In the case of wallpaper, if any leftover wallpaper is available, getting a patch to match exactly can be very difficult. The end result may be the entire wall may need to be repaired, repainted, and/or re-wallpapered.

As used herein, the term “escutcheon” is defined as a device that at least partially surrounds another device to protect, conceal, other otherwise integrate the other device into its surroundings, such as, but not limited to, a wall-mounted thermostat. The device may be a thermostat or another device or object.

What is needed then is an escutcheon that covers the footprint of the old thermostat and also engages the profile of the new thermostat to provide a clean and professional appearance that is also easy to install, without requiring repainting, wallpaper repair, or additional touch-up work.

### SUMMARY

The present disclosure overcomes the problems and disadvantages associated with current strategies and designs and provides new tools and methods for a thermostat escutcheon.

One embodiment of the disclosure is directed to an escutcheon that surrounds a thermostat or other device or object.

Another embodiment of the disclosure is directed to an escutcheon that covers the footprint of a removed thermostat.

Another embodiment of the disclosure is directed to a thermostat escutcheon that surrounds a new thermostat and covers a portion of a footprint of a removed thermostat not covered by the new thermostat.

Another embodiment of the disclosure is directed to a thermostat escutcheon that surrounds a thermostat with a single element.

Another embodiment of the disclosure is directed to a thermostat escutcheon that surrounds a thermostat with a plurality of elements.

Another embodiment of the disclosure is directed to a thermostat escutcheon that includes customizable elements.

Another embodiment of the disclosure is directed to a thermostat escutcheon that includes customizable elements, such as but not limited to a paintable surface, addition/subtraction of decorative elements, and quick-change components.

Another embodiment of the disclosure is directed to a thermostat escutcheon including an escutcheon element, a mating surface, disposed about at least a portion of the escutcheon element, where at least one of the escutcheon element and the mating surface selectively engage the device secured to a surface to at least partially surround the device.

Another embodiment of the disclosure is directed to a thermostat escutcheon a second escutcheon element, where the second escutcheon element includes a second mating surface disposed about at least a portion of the second escutcheon element and selectively engages at least one of the first escutcheon element, the second escutcheon element, and the device.

Another embodiment of the disclosure is directed to a thermostat escutcheon including at least one connector to selectively join the first escutcheon element and the second escutcheon element.

Another embodiment of the disclosure is directed to a thermostat escutcheon including a third escutcheon element, where the third escutcheon element includes a third mating surface disposed about at least a portion of the third escutcheon element and selectively engages at least one of the first escutcheon element, the second escutcheon element, and the device.

Another embodiment of the disclosure is directed to a thermostat escutcheon including at least one connector to selectively join the first escutcheon element, the second escutcheon element, and the third escutcheon element.

Another embodiment of the disclosure is directed to a thermostat escutcheon including a fourth escutcheon element, where the fourth escutcheon element includes a fourth mating surface disposed about at least a portion of the fourth escutcheon element and selectively engages at least one of the first escutcheon element, the second escutcheon element, the third escutcheon element, and the device.

Another embodiment of the disclosure is directed to a thermostat escutcheon including at least one connector to selectively join the first escutcheon element, the second escutcheon element, the third escutcheon element, and the fourth escutcheon element.

Another embodiment of the disclosure is directed to a thermostat escutcheon including an insert.

Another embodiment of the disclosure is directed to a thermostat escutcheon where the insert further comprises an interior volume for receiving at least one object.

Another embodiment of the disclosure is directed to a thermostat escutcheon where the insert is selectively replaceable with a second insert.

Another embodiment of the disclosure is directed to a thermostat escutcheon where the insert is a video display.

Another embodiment of the disclosure is directed to a thermostat escutcheon where the escutcheon element includes at least one fastener element to secure the escutcheon.

Another embodiment of the disclosure is directed to a thermostat escutcheon including a first segment, a second segment that selectively engages the first segment, a plurality of mating surfaces disposed about at least a portion of the first segment and the second segment, where the mating surfaces are configured to engage at least a portion of the thermostat and the first and the second segment.

Another embodiment of the disclosure is directed to a thermostat escutcheon including at least one connector for selectively joining the first segment and the second segment.

Another embodiment of the disclosure is directed to a thermostat escutcheon where the first segment and the second segment include surface decorations disposed on at least one surface of the first segment and the second segment.

Another embodiment of the disclosure is directed to a thermostat escutcheon where the surface decorations include a plurality of inserts.

Another embodiment of the disclosure is directed to a thermostat escutcheon including a plurality of segments that selectively engage at least another one of the plurality of segments, a plurality of mating surfaces disposed about at least a portion of the plurality of segments, where the mating surfaces are configured to engage at least a portion of the thermostat and the plurality of segments, and a plurality of surface decorations disposed on at least one of the plurality of segments.

Another embodiment of the disclosure is directed to a thermostat escutcheon where the surface decorations include a plurality of inserts.

Another embodiment of the disclosure is directed to a thermostat escutcheon where the inserts include at least one video display.

Another embodiment of the disclosure is directed to a thermostat escutcheon where the plurality of segments include at least one fastener to secure the plurality of segments.

Other embodiments and advantages of the disclosure are set forth in part in the description, which follows, and in part, may be obvious from this description, or may be learned from the practice of the disclosure.

### DESCRIPTION OF THE FIGURES

The disclosure is described in greater detail by way of example only and with reference to the attached drawings, in which:

FIG. 1 is a front view of an embodiment of the present disclosure;

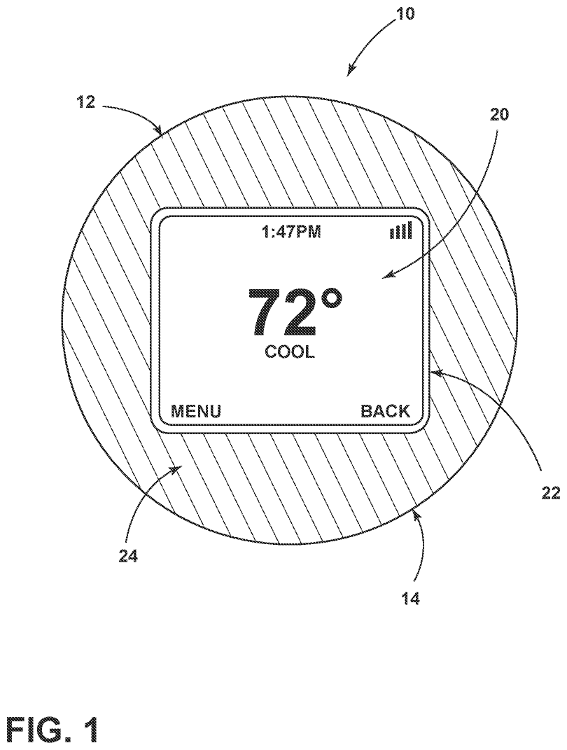

FIG. 2 is a front view of an embodiment of the present disclosure;

FIG. 3 is a front view of an embodiment of the present disclosure;

FIG. 4 is a partial cutaway view of an embodiment of the present disclosure;

FIG. 5 is a partial cutaway view of an embodiment of the present disclosure; and

FIG. 6 illustrates several embodiments of the present disclosure.

### DESCRIPTION OF THE DISCLOSURE

As embodied and broadly described herein in the Figures, the present disclosure is directed to thermostat escutcheon (“escutcheon”) 10.

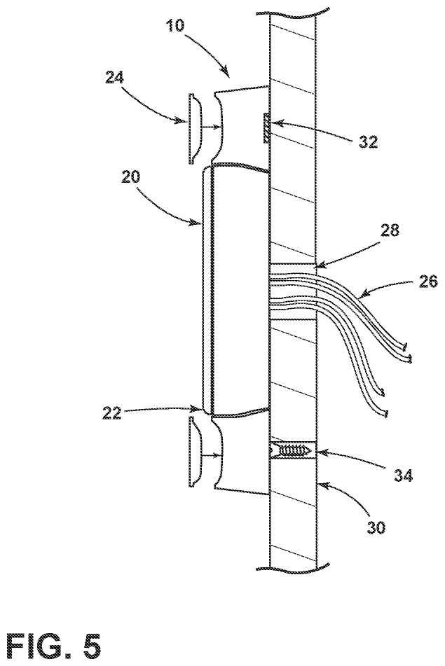

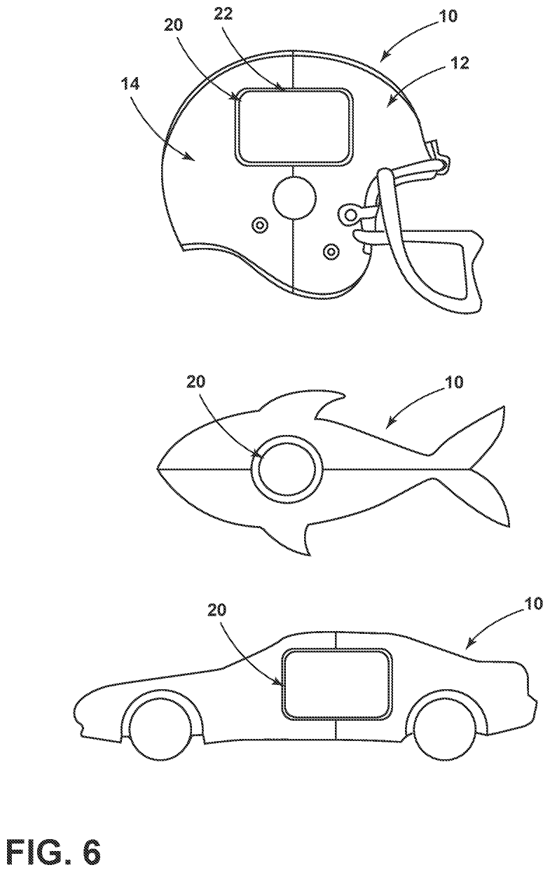

According to one embodiment of the disclosure, escutcheon 10 may be in the form of one or more portions, such as shown in the Figures. A first portion 12 may be disposed above the (new or replacement) wall-mounted thermostat 20. A second portion 14, third portion 16, and/or fourth portion 18 (for example and without limitation) may be disposed beneath the wall-mounted thermostat 20. A mating surface 22 of first portion 12 and second portion 14 is provided that selectively engages the wall-mounted thermostat 20 and/or parts of first portion 12 and second portion 14. In embodiments, one or more portions may include a mechanical and/or electrical device configured to selectively join at least one portion to another portion. The mating surface 22 may be configured to prevent any portion of the wall (see FIGS. 5-6) from being visible when viewing the escutcheon 10 and the thermostat 20. In this configuration then, there is no need for any repainting, re-wallpapering, or other touch-up of the wall as the escutcheon completely covers the wall immediately surrounding the thermostat 20. In other words, the wall immediately surrounding the thermostat 20 may be completely covered when viewing the thermostat 20.

In embodiments, the first portion 12, second portion 14, third portion 16, and fourth portion 18, for example, may be configured to engage at least a portion of thermostat 20. In other words, thermostat 20 may include a surface profile or contour that first portion 12 (and/or other portions) engage to present a desired interface that may include some or all of mating surface 22. In embodiments, mating surface 22 may be present between first portion 12 and/or second portion 14. In embodiments, mating surface 22 may be different between first portion 12 and/or second portion 14 in comparison to mating surface 22 between thermostat 20 and first portion 12 and/or second portion 14. For example, and without limitation, the mating surface 22 between first portion 12 and/or second portion 14 may be nearly flush, or at least perceptibly so, while the mating surface 22 between thermostat 20 and first portion 12 and/or second portion 14 may not be nearly flush. In other examples, the opposite may be case. In still other embodiments, variations may be present involving the characteristics of mating surface 22 that incorporate various design elements.

The escutcheon 10 may be utilized in a variety of situations, such as, but not limited to, accessorizing an existing thermostat 20. In this situation, the thermostat 20 is already installed and a consumer decides to accessorize the thermostat 20 by adding escutcheon 10. Often consumers tire of the look of the thermostat 20 and escutcheon 10 changes the appearance without the need to remove or replace the thermostat 20.

Removal of the thermostat 20 can be fraught with difficulties. One such difficulty is the attachment method securing the thermostat 20 to the wall 30. Often, thermostat 20 is secured using one or, more likely, multiple fasteners 34, such as drywall screw anchor devices, or screws directly engaging wood either through drywall or on a visible wooden surface. In other situations, the thermostat 20 may be secured using concrete or stucco anchors. In still other situations, adhesive may be used. Typically, these attachment devices are one-time use devices; in other words, once removed they may not work as well again. Thus, there is an incentive to not disturb the thermostat 20 once it is engaged to the wall 30.

Another difficulty is that thermostat 20 is typically connected to a plurality of wires 26 that extend into the wall 30. These wires 26 are often of a length that does not allow for much movement of thermostat 20 once it is disconnected from the wall 34. Particularly in an older thermostat (or other device) application, wires 26 may be brittle, in addition, and therefore any movement may cause damage that prevents the thermostat 20 from operating without repair to the wires 26. Further, the wires 26 are connected in some thermostats 20, directly to the thermostat 20. Typically, consumers are not familiar with these wires and the importance of connecting the correct wires 26 to the correct terminals on the thermostat 20. Thus, if a wire 26 or two is disconnected, the consumer may face a difficult situation in determining the correct repair, particularly if additional terminals are available. Even if the thermostat 20 is secured to a mounting plate, repeated removal of the thermostat 20 may result in the thermostat 20 not fitting securely or possible damage to the mounting plate/thermostat 20 interface.

Still another difficulty is the risk of losing one or more wires 26 through the hole 28 in the wall 30. Often the wires 26 are installed during construction, and accessing the wires may be challenging later (or much later) for the typical consumer, necessitating an electrician or other repair person to come out and “fish” the wires 26 out of the wall 30 and reconnect them to thermostat 20. As a result, consumers are reluctant to disturb or otherwise touch the thermostat once it is mounted and operating correctly on the wall (or another surface).

As discussed herein, often when an existing thermostat (not shown) is replaced with the thermostat 20 the mounting positions, holes, painted or wallpapered surfaces often do not completely line up. In many situations, the shape and general configuration of the old thermostat often does not line up with the shape and general configuration of the new thermostat 20. Because of this mis-match, consumers are often left with a difficult decision, one that may preclude their choosing to replace their old thermostat with an updated, modern thermostat 20. In other words, the thermostat 20 as installed on the wall leaves some repair, retouch, or other rework required to make the thermostat 20 installation appear to be professional, neat, and otherwise desirable. Apart from the added convenience of a modern thermostat 20, additional energy savings may not be realized due to the difficulties in making the new thermostat 20 easily adaptable into the thermostat mounting location.

In one embodiment of the disclosure, the first portion 12 and the second portion 14 of escutcheon 10 may be formed in halves (or some other percentage which may be unequal). It should be understood that escutcheon 10 may be formed of a single portion or multiple portions, and if in multiple portions, those portions may not necessarily be symmetrical in size, shape, or volume.

First portion 12 and second portion 14 may, at least partially, surround thermostat 20 and include one or more mating surfaces 22. In this embodiment, mating surfaces 22 extend around thermostat 20 and also between first portion 12 and second portion 14. It should be understood that mating surfaces 22 may be uniform, dissimilar, or a mixture thereof. As shown in the Figures, mating surfaces 22 shown to be uniform but this exemplary only and not limiting. In addition, the mating surfaces 22 may be integrated into first portion 12 and/or second portion 14. Alternatively, mating surface 22 may be configured as a backing plate upon which at least first portion 12 and/or second portion 12 may be mounted. Additionally, mating surface 22 may be configured as a backing plate of more than one element, such that the exposed, viewable portions of mating surface 22 may not show joints or other undesirable elements.

Mating surface 22 may vary based on its location. For example, mating surface 22 may be configured to engage the surface of a particular type, or brand of thermostat 22. In this configuration, mating surface 22 may approach or touch a portion of thermostat 22, both for aesthetics and also to prevent the viewing of the wall or other surface upon which thermostat 20 is mounted.

Surface decoration 24 may also be included on one or more surfaces of escutcheon 10, including but not limited to, first portion 12 and second portion 14. For example, surface decoration 24 may be a simple texture for receiving paint. In other embodiments, surface decoration 24 may be more (or less) complicated, detailed, symmetrical, or asymmetrical, for example. In other embodiments, surface decoration 24 may include one or more removable or interchangeable portions (as shown in FIG. 5). It is to be understood that surface decoration 24 may include novelty or other commercial images, representations, shapes, logos, and other designs. For example, surface decoration 24 may include sports team logos or other themes such as birds, children's characters, comic book characters, and the like. It is also understood that surface decoration 24 may be selectively replaceable, to allow for changes in appearance as desired.

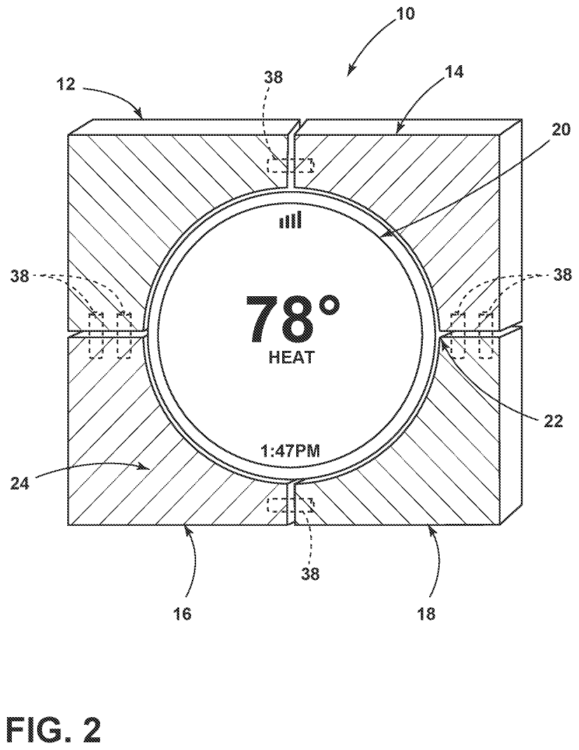

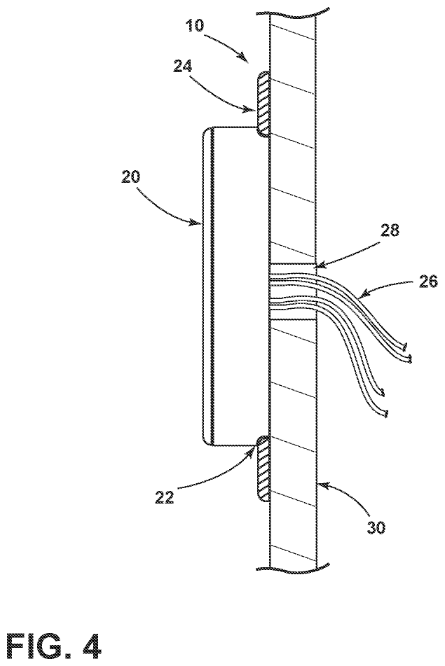

FIG. 2 illustrates another embodiment of the present disclosure. Escutcheon 10 is shown divided into four portions (which, in this embodiment appear equal but it should be understood that this configuration is exemplary only and not limiting)—first portion 12, second portion 14, third portion 16, and fourth portion 18. Surrounded by escutcheon 10 is thermostat 20. A plurality of mating surfaces 22 that include at least partially, first portion 12, second portion 14, third portion 16, and fourth portion 18 engage thermostat 20 and prevent and/or minimize the exposure of the wall (see FIGS. 4-5) behind escutcheon 10 and thermostat 20. In this embodiment, the four portions 12, 14, 16, and 18 are of equal size and disposed around thermostat 20. However, it should be understood that in other embodiments the portions of escutcheon 20 may be of different sizes. For example, escutcheon 10 may be configured in the shape of an object such as a football helmet, a fish, a car, or other object (see FIG. 6). A plurality (or at least one) connector 38 may be disposed in one or more of first portion 12, second portion 14, third portion 16, and fourth portion 18. Connector 38 may be configured to allow for one or more of first portion 12, second portion 14, third portion 16, and fourth portion 18 to be joined to another portion, or mating surface 22, if so, configured as described herein. Connector 38 may be configured as a variety of joining devices, such as, but not limited to, magnets, screws, bolts, adhesives, hook-and-loop fasteners, or another joining device. In other embodiments, connector 38 may be configured or integrated into one or more of first portion 12, second portion 14, third portion 16, and fourth portion 18, to allow for a mechanical connection, such as a tongue-and-groove, snap-fit, or friction fit, or other configuration that allows for first portion 12, second portion 14, third portion 16, and fourth portion 18 to be joined to one or more other portions and/or mating surface 22.

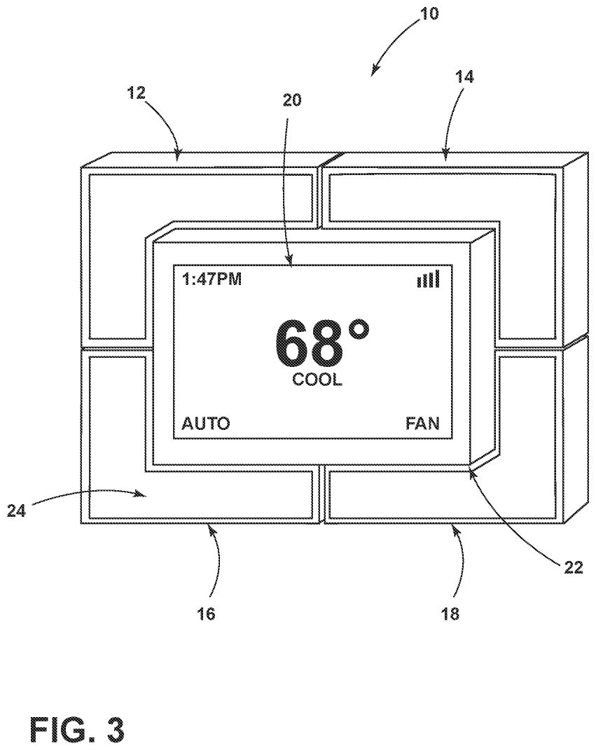

FIG. 3 illustrates another embodiment of the present disclosure. Escutcheon 10 is shown in four portions—first portion 12, second portion 14, third portion 16, and fourth portion 18. Thermostat 20 is shown disposed surrounded by the portions of escutcheon 10. It should be understood that thermostat 20 may be configured in a plurality of shapes and escutcheon 10 likewise may be configured to engage a plurality of configurations or shapes of thermostat 20. As disclosed herein, the portions of escutcheon 10 may or may not be of similar shape and/or symmetry. Mating surfaces 22 of escutcheon 10 may engage thermostat 20 and/or minimize or prevent the viewing of the wall (see FIGS. 5-6) behind escutcheon 10 and thermostat 20. In this embodiment, each portion of escutcheon 10 includes a surface decoration 24. In some embodiments, surface decoration 24 may be selectively removable and/or replaceable in order to change the appearance of escutcheon 10. For example, surface decoration 24 may include a texture that may be paintable or may include some other surface treatment (e.g., plating, molded color, etc.). In other embodiments, escutcheon 10 and/or surface treatment 24 may include other decorative elements, including electronic components (e.g., light emitting diodes, etc.). In still other embodiments, first portion 12, second portion 14, third portion 16, and fourth portion 18 may include removable inserts 25 to allow for the surface decoration 24 to be changed.

Inserts 25 may be configured in one or more portions of escutcheon 10. In other embodiments, inserts 25 may be omitted from escutcheon 10. In still other embodiments, inserts 25 may be added to escutcheon 10 after installation. In one embodiment, inserts 25 may be configured to receive pictures or images.

For example, inserts 25 may be configured to hold images, such as family photos or other memorabilia to be stored and viewed in escutcheon 10. A clear portion of inserts 25 may trap or otherwise secure pictures in place within at least a portion of escutcheon 10, such as in a diorama, or a three-dimensional volume or space.

In another exemplary embodiment, inserts 25 may be configured as one or more video screens. These screens may be LCD or another suitable type, and may include a processor, a memory, and a power source. Each insert 25 may be configured as a separate, independent screen or may be configured to coordinate images between the plurality of inserts 25.

In another exemplary embodiment, inserts 25 may be configured to include an internal volume, to display various objects. These objects may include a particular theme, or scrapbook-type display. For example, a fishing enthusiast may choose to display fishing lures and/or photos of caught fish in one or more inserts 25 when escutcheon 10. The objects and/or images contained within inserts 25 may be updated or changed as desired. In this way, the thermostat 20 and escutcheon 10 may be customized or bespoke to a particular consumer, for a particular location, and a particular period of time.

FIG. 4 illustrates another embodiment of the present disclosure. Escutcheon 10 is shown with at least portion 12 disposed about thermostat 20 mounted to a wall 30. Wall 30 includes a hole 28 through which a plurality of wires 26 connected to thermostat 20 extend. Mating surfaces 22 of escutcheon 10 engage the perimeter or sides of thermostat 20 in order to avoid the surface of wall 30 from being visible when viewing the thermostat 20. Escutcheon 10 also includes surface decoration 24 which may be integrated into escutcheon 10 or a separate component as disclosed herein. Surface decoration 24 may include a texture to receive paint or another coating (e.g., plating). Surface decoration 24 may include one or more inserts 25.

FIG. 5 illustrates another embodiment of the present disclosure. Escutcheon 10 is shown partially cutaway around thermostat 20 mounted to a wall 30. Escutcheon 10 may be mounted to wall 30 using an adhesive pad 32 and/or a fastener 34. Wall 30 includes a hole 28 through which a plurality of wires 26 connected to thermostat 20 extend. Mating surfaces 22 of escutcheon 10 engage the perimeter or sides of thermostat 20 in order to avoid or minimize the surface of wall 30 from being visible when viewing the thermostat 20. Escutcheon 10 also includes surface decoration 24 as a separate, selectively removable component with inserts 25, selectively detachable from escutcheon 10.

FIG. 6 illustrates several embodiments of the present disclosure. Escutcheon 10 is shown configured in exemplary shapes—a football helmet, a fish and a car. Within, or surrounded by, escutcheon 10 is thermostat 20. Escutcheon 10 in a variety of shapes or configurations may include one or more portions as disclosed herein. For example, escutcheon 10 as a football helmet may be formed in a single portion or multiple portions. Surface decorations 24 for the football helmet escutcheon 10 may include a team logo. Surface decorations 24 for the fish escutcheon may include life-like coloring including gills and scales. Surface decorations 24 for the car escutcheon may include colors, racing decals, sponsors and other automotive-related images and logos. It is also contemplated that unique or otherwise proprietary logos, designs and images may be incorporated into escutcheon 10 and/or surface decorations 24. In other embodiments, surface decorations 24 may include one or more inserts 25 as described herein.

In embodiments, escutcheon 10 may be configured in a variety of shapes, such as shapes belonging to, or relating to activities, sports, entertainment, hobbies, as well as architectural or other thematic shapes and configurations, or pluralities thereof.

For example, and without limitation, escutcheon 10 may be configured to represent a sports team logo, as an officially-licensed product of a particular sports league or team.

In another example, as shown in FIG. 6, escutcheon 10 may be configured as a sports team helmet, complete with logo and team colors. In addition, escutcheon 10 may be re-configurable if the consumer decides to change allegiance to a particular team or moves to a new city and supports that particular team.

In another example, a corporation may choose to incorporate its logo or a logo of one of its products into escutcheon 10 as a promotional item.

In yet another example, for hobbyists, escutcheon 10 may be configured in a shape relevant to their particular hobby. For example, fishing enthusiasts may want escutcheon 10 configured in a particular fish shape. Automotive hobbyists may want escutcheon 10 in the shape of their dream car or favorite car brand.

In yet another example, escutcheon 10 may be configured as a piece of artwork in itself, as a portrait or other shape or object that may disguise or cause thermostat 10 to otherwise blend into the background. For example, escutcheon 10 could be configured to disguise thermostat 10 as another electronic device and include other electronic features to further the disguise and/or illusion.

It should be understood that the escutcheon 10 of the present disclosure may be constructed of a variety of materials and techniques. For example, and without limitation, the escutcheon 10 may be constructed of plastic, polymers, wood, composite materials, metal, or any other existing or yet to be developed material, or a combination thereof. The escutcheon 10 may be manufactured using a variety of techniques, including but not limited to injection molding, additive manufacturing, machining, or a combination of these or other techniques.

The preceding examples illustrate embodiments of the disclosure, but should not be viewed as limiting the scope of the disclosure.

Other embodiments and uses of the disclosure will be apparent to those skilled in the art from consideration of the specification and practice of the disclosure disclosed herein. All references cited herein, including all publications, U.S. and foreign patents and patent applications, are specifically and entirely incorporated by reference. The term comprising, where ever used, is intended to include the terms consisting and consisting essentially of. Furthermore, the terms comprising, including, and containing are not intended to be limiting. It is intended that the specification and examples be considered exemplary only with the true scope and spirit of the disclosure indicated by the following claims.

1. An escutcheon for a device comprising:
an escutcheon element;
a mating surface, disposed about at least a portion of the escutcheon element;
wherein at least one of the escutcheon element and the mating surface selectively engage the device secured to a surface to at least partially surround the device.

2. The escutcheon of claim 1, further comprising:
a second escutcheon element, wherein the second escutcheon element includes a second mating surface disposed about at least a portion of the second escutcheon element and selectively engages at least one of the first escutcheon element, the second escutcheon element, and the device.

3. The escutcheon of claim 2, further comprising at least one connector to selectively join the first escutcheon element and the second escutcheon element.

4. The escutcheon of claim 2, further comprising:
a third escutcheon element, wherein the third escutcheon element includes a third mating surface disposed about at least a portion of the third escutcheon element and selectively engages at least one of the first escutcheon element, the second escutcheon element, and the device.

5. The escutcheon of claim 4, further comprising at least one connector to selectively join the first escutcheon element, the second escutcheon element, and the third escutcheon element.

6. The escutcheon of claim 4, further comprising:
a fourth escutcheon element, wherein the fourth escutcheon element includes a fourth mating surface disposed about at least a portion of the fourth escutcheon element and selectively engages at least one of the first escutcheon element, the second escutcheon element, the third escutcheon element, and the device.

7. The escutcheon of claim 6, further comprising at least one connector to selectively join the first escutcheon element, the second escutcheon element, the third escutcheon element, and the fourth escutcheon element.

8. The escutcheon of claim 1, wherein the escutcheon element further comprises an insert.

9. The escutcheon of claim 8, wherein the insert further comprises an interior volume for receiving at least one object.

10. The escutcheon of claim 8, wherein the insert is selectively replaceable with a second insert.

11. The escutcheon of claim 8, wherein the insert is a video display.

12. The escutcheon of claim 1, wherein the escutcheon element includes at least one fastener element to secure the escutcheon.

13. An escutcheon for a thermostat, the escutcheon comprising:
a first segment;
a second segment that selectively engages the first segment;
a plurality of mating surfaces disposed about at least a portion of the first segment and the second segment, wherein the mating surfaces are configured to engage at least a portion of the thermostat and the first and the second segment.

14. The escutcheon of claim 13, further comprising at least one connector for selectively joining the first segment and the second segment.

15. The escutcheon of claim 13, wherein the first segment and the second segment include surface decorations disposed on at least one surface of the first segment and the second segment.

16. The escutcheon of claim 15, wherein the surface decorations include a plurality of inserts.

17. An escutcheon for a thermostat, the escutcheon comprising:
a plurality of segments that selectively engage at least another one of the plurality of segments;
a plurality of mating surfaces disposed about at least a portion of the plurality of segments, wherein the mating surfaces are configured to
engage at least a portion of the thermostat and the plurality of segments; and
a plurality of surface decorations disposed on at least one of the plurality of segments.

18. The escutcheon of claim 17, wherein the surface decorations include a plurality of inserts.

19. The escutcheon of claim 18, wherein the inserts include at least one video display.

20. The escutcheon of claim 17, wherein the plurality of segments include at least one fastener to secure the plurality of segments.
